(19) United States
(12) Patent Application Publication
(10) Pub. No.: US 2023/0052532 A1
(43) Pub. Date: Feb. 16, 2023

(54) VAPOR DEPOSITION APPARATUS

(71) Applicant: TCL CHINA STAR OPTOELECTRONICS TECHNOLOGY CO., LTD., Shenzhen, Guangdong (CN)

(72) Inventor: Zhiwu WANG, Shenzhen, Guangdong (CN)

(21) Appl. No.: 16/768,539

(22) PCT Filed: May 20, 2020
(86) PCT No.: PCT/CN2020/091207

§ 371 Date: May 29, 2020

(30) Foreign Application Priority Data
May 8, 2020 (CN) 2020 10380106.4

(51) Int. Cl. C23C 16/513; C23C 16/44; C23C 16/455

(52) U.S. Cl. CPC C23C 16/513; C23C 16/4405; C23C 16/45561

(57) ABSTRACT

The present application discloses a vapor deposition apparatus, including: a reaction chamber, a gas spraying device, and a cleaning gas channel, wherein the gas spraying device includes a reaction gas channel, and the reaction gas channel includes an outlet communicating with the reaction chamber; and the cleaning gas channel is spaced apart from the reaction gas channel, such that the probability of generating the residual produce in the reaction chamber can be reduced, and the uniformity of film formation and the utilization rate of the machine are improved.

### BACKGROUND OF INVENTION

### Field of Invention

The present application relates to a field of display technology, in particular to a vapor deposition apparatus.

### Description of Prior Art

A plasma enhanced chemical vapor deposition (PECVD) apparatus will deposit the desired film on a substrate during a film formation process, and certain produces will remain in an inner wall of a chamber. Accumulation to a certain amount will cause peeling, resulting in an increased probability of occurrence of produce particle problems. In order to ensure the quality of the product, the chamber will be cleaned after the produces have accumulated to a certain thickness, but the cleaning gas used in the cleaning process is likely to make the inner wall of the chamber rough and impact the uniformity of film formation. Therefore, regular maintenance is required to ensure the quality of the film formation, but this will impact the utilization rate of the machine.

### SUMMARY OF INVENTION

Embodiments of the present application provide a vapor deposition apparatus, which can reduce the probability of generating the residual produce in the reaction chamber, and improve the uniformity of film formation and the utilization rate of the machine.

An embodiment of the present application provides a vapor deposition apparatus, including: a reaction chamber, a gas spraying device, and a cleaning gas channel, wherein

the gas spraying device includes a reaction gas channel, and the reaction gas channel includes an outlet communicating with the reaction chamber; and

the cleaning gas channel is spaced apart from the reaction gas channel.

In the vapor deposition apparatus, the cleaning gas channel is located below the outlet of the reaction gas channel.

In the vapor deposition apparatus, the reaction gas channel includes a first reaction gas channel and a second reaction gas channel spaced apart from each other, the first reaction gas channel includes a first outlet communicating with the reaction chamber, the second reaction gas channel includes a second outlet communicating with the reaction chamber, and the cleaning gas channel is located below the first outlet and the second outlet.

In the vapor deposition apparatus, a back plate located above the gas spraying device is further included, wherein the back plate is provided with a gas inlet communicating with outside of the reaction chamber and communicating with the reaction gas channel.

In the vapor deposition apparatus, the first reaction gas channel communicates with outside of the reaction chamber, a first gas enters the reaction chamber through the first outlet of the first reaction gas channel, the second reaction gas channel communicates with the outside of the reaction chamber, and a second gas enters the reaction chamber through the second outlet of the second reaction gas channel.

In the vapor deposition apparatus, a back plate located above the gas spraying device is further included, wherein the back plate is provided with a first gas inlet communicating with outside of the reaction chamber and communicating with the reaction gas channel, and a second gas inlet communicating with the outside of the reaction chamber and communicating with the second reaction gas channel.

In the vapor deposition apparatus, a size of the first reaction gas channel is greater than or equal to 0.2 mm and less than or equal to 0.6 mm.

In the vapor deposition apparatus, a size of the second reaction gas channel is greater than or equal to 0.2 mm and less than or equal to 0.6 mm.

In the vapor deposition apparatus, n a top view, the first outlet is one or a combination of a circle, a bar, and a polygon.

In the vapor deposition apparatus, in a top view, the second outlet is one or a combination of a circle, a bar, and a polygon.

In the vapor deposition apparatus, the first gas includes one of an oxidizing gas and a reducing gas.

In the vapor deposition apparatus, the second gas includes the other one of the oxidizing gas and the reducing gas.

In the vapor deposition apparatus, the oxidizing gas includes oxygen and/or nitrous oxide; and the reducing gas includes silane and/or phosphine.

In the vapor deposition apparatus, a cleaning gas enters the reaction chamber through the cleaning gas channel, and the cleaning gas includes nitrogen trifluoride and/or argon gas.

In the vapor deposition apparatus, a size of the reaction gas channel is greater than or equal to 0.2 mm and less than or equal to 0.6 mm.

In the vapor deposition apparatus, the size of the reaction gas channel is equal to 0.3 mm.

In the vapor deposition apparatus, a stage directly facing the outlet is further included.

Compared with the prior art, the vapor deposition apparatus provided in an embodiment of the present application includes: a reaction chamber, a gas spraying device, and a cleaning gas channel, wherein the gas spraying device includes a reaction gas channel, and the reaction gas channel includes an outlet communicating with the reaction chamber; and the cleaning gas channel is spaced apart from the reaction gas channel, such that the probability of generating the residual produce in the reaction chamber can be reduced, and the uniformity of film formation and the utilization rate of the machine are improved.

### BRIEF DESCRIPTION OF DRAWINGS

FIGS. 1A-1B are schematic structural diagrams of a vapor deposition apparatus provided by embodiments of the present application.

FIGS. 2A-2B are schematic structural diagrams of a gas spraying device provided by embodiments of the present application . . .

### DETAILED DESCRIPTION OF PREFERRED EMBODIMENTS

In order to make the purpose, technical solutions and effects of the present application clearer and more definite, the present application will be described in further detail below with reference to the accompanying drawings and examples. It should be understood that the specific embodiments described herein are only used to explain the present application and are not intended to limit the present application.

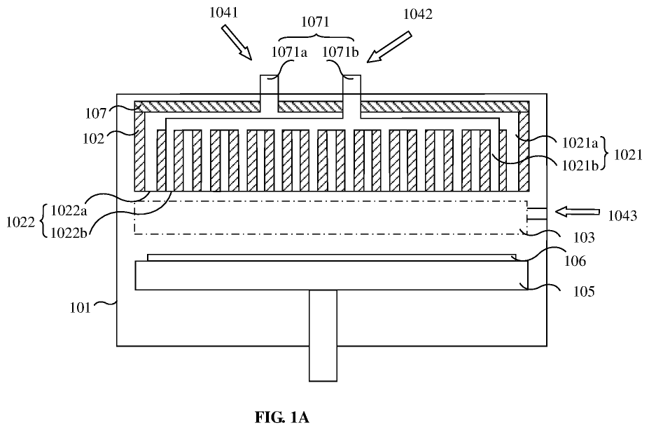

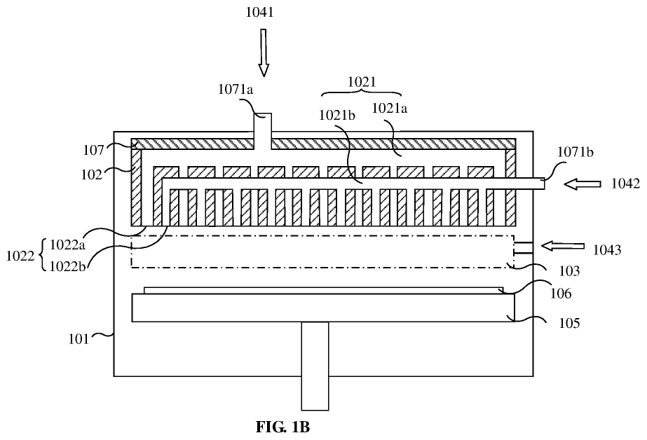

Specifically, referring to FIGS. 1A-1B, FIGS. 1A-1B are schematic structural diagrams of a vapor deposition apparatus provided by embodiments of the present application. The vapor deposition apparatus includes: a reaction chamber 101, a gas spraying device 102, and a cleaning gas channel 103.

The gas spraying device 102 includes a reaction gas channel 1021, and the reaction gas channel 1021 includes an outlet 1022 communicating with the reaction chamber 101.

The cleaning gas channel 103 and the reaction gas channel 102 are spaced apart from each other, so that the cleaning gas 1043 can directly enter the reaction chamber 101 through the cleaning gas channel 103, to prevent an equipment such as the gas spraying device or the back plate 107 in the chamber 101 from being etched by the cleaning gas 1043, which impacts the quality of film formation and the utilization rate of the machine.

The cleaning gas 1043 includes nitrogen trifluoride and/or argon gas. The vapor deposition apparatus may inject the cleaning gas 1043 into the reaction chamber 101 after 5 to 15 times of the film formation processes to remove the residual produces in the reaction chamber 101 during the film formation process, thereby ensuring cleanliness of the reaction chamber 101.

Specifically, Still referring to FIG. 1A to FIG. 1B, the cleaning gas channel 103 is located below the outlet 1022 of the reaction gas channel 102, so that the cleaning gas can directly enter the reaction from the cleaning gas channel 103 In the chamber 101, the number of inspections required for the gas spraying device or the back plate in the reaction chamber 101 to be etched is reduced, and the machine utilization rate is improved.

The outlet 1022 is directly opposite to the stage 105. During the film formation process, the substrate 106 is placed on the stage 105, and the reaction gas flowing through the reaction gas channel 1021 undergoes a film formation reaction on the surface of the substrate 106.

A size of the reaction gas channel 1021 is greater than or equal to 0.2 mm and less than or equal to 0.6 mm; and further, the size of the reaction gas channel 1021 is equal to 0.3 mm.

Furthermore, the reaction gas channel 1021 includes a first reaction gas channel 1021a and a second reaction gas channel 1021b that are spaced apart from each other. The first reaction gas channel 1021a includes a first outlet 1022a that communicates with the reaction chamber 101. The second reaction gas channel 1021b includes a second outlet 1022b that communicates with the reaction chamber 101. The cleaning gas channel 103 is located below the first outlet 1022a and the second outlet 1022b, so as to improve the utilization rate of the machine and ensure that when the reaction gas enters the reaction chamber 101, residue is prevented from appearing in a non-film forming area of the reaction chamber 101, which impacts accuracy of the film formation. The non-film forming area refers to an area on the stage 105 except for the area on which the substrate 106 is located in the reaction chamber 101.

The first reaction gas channel 1021a communicates with the outside of the reaction chamber 101, and the first gas 1041 enters the reaction chamber 101 through the first outlet 1022a of the first reaction gas channel 1021a. The second reaction gas channel 1021b communicates with the outside of the reaction chamber 101, and the second gas 1042 enters the reaction chamber 101 through the second outlet 1022b of the second reaction gas channel 1021b. The first outlet 1022a and the second outlet 1022b is set to face the stage 105, and the first gas 1041 and the second gas 1042 are subjected to a film-forming reaction on a surface of the substrate 106.

By spacing the first reaction gas channel 1021a apart from the second reaction gas channel 1021b, the first gas 1041 and the second gas 1042 can be prevented from flowing through a same reaction gas channel, so that the first gas 1041 and the second gas 1042 can be subjected to a chemical reaction only after flowing out of the first outlet 1022a and the second outlet 1022b, thereby reducing the probability of generating residual produces in the non-film forming area of the reaction chamber 101, avoiding the problem of falling off of the residual produces and generation of particles in the film formation process.

In addition, during the film formation process, pumping will be continuously conducted from the bottom of the reaction chamber 101, so the first gas 1041 and the second gas 1042 will not return to the first reaction gas channel 1021a and the second reaction gas channels 1021b.

The first gas 1041 includes one of an oxidizing gas and a reducing gas; and the second gas 1042 includes the other one of the oxidizing gas and the reducing gas.

Specifically, the oxidizing gas includes oxygen and/or nitrous oxide; and the reducing gas includes silane and/or phosphine.

In addition, the first gas 1041 and the second gas 1042 flowing through the first reaction gas channel 1021a and the second reaction gas channel 1021b may also be mixed gases. When the first gas 1041 and the second gas 1042 are mixed gases, it is necessary to ensure that no chemical reaction occurs between the gases flowing through the same reaction gas channel 1021 to block the reaction gas channel 1021 or cause a safety accident. That is, when the first gas 1041 is a mixed gas, it is necessary to ensure that the first gas 1041 flowing through the first reaction gas channel 1021a will not be subjected to a chemical reaction to block the first reaction gas channel 1021a or cause a safety accident. Similarly, when the second gas 1042 is a mixed gas, it is necessary to ensure that the second gas 1042 flowing through the second reaction gas channel 1021b will not be subjected to a chemical reaction to block the second reaction gas channel 1021b or cause a safety accident.

Since the first gas 1041 and the second gas 1042 flow into the reaction chamber 101 through the different reaction gas channels 1021 respectively, when a size of the gas spraying device 102 is constant, the channel size of the two reaction gas channels 1021 will be smaller than the channel size of one reaction gas channel 1021 provided alone. Specifically, the channel size of the first reaction gas channel 1021a is greater than or equal to 0.2 mm and less than or equal to 0.6 mm; and further, the channel size of the first reaction gas channel 1021a is equal to 0.3 mm. Similarly, the channel size of the second reaction gas channel 1021b is greater than or equal to 0.2 mm and less than or equal to 0.6 mm; and Further, the channel size of the second reaction gas channel 1021b is equal to 0.3 mm.

As the channel sizes of the first reaction gas channel 1021a and the second reaction gas channel 1021b become thinner, one with a lower flow rate of the first gas 1041 and the second gas 1042 can be distributed more uniformly when entering the reaction chamber 101, to improve the uniformity of film formation.

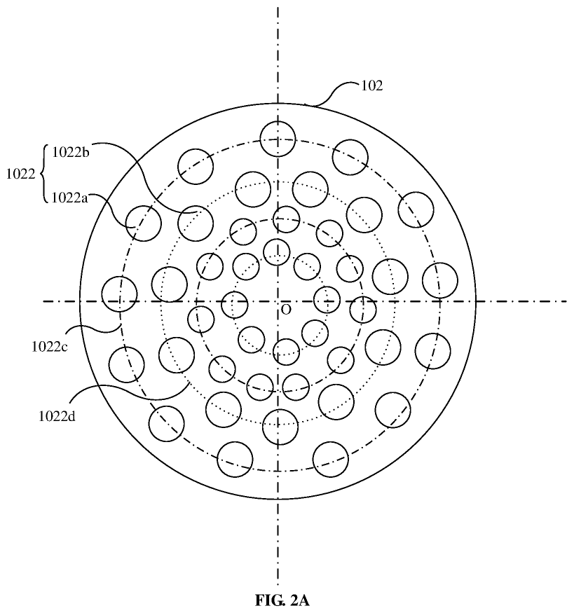

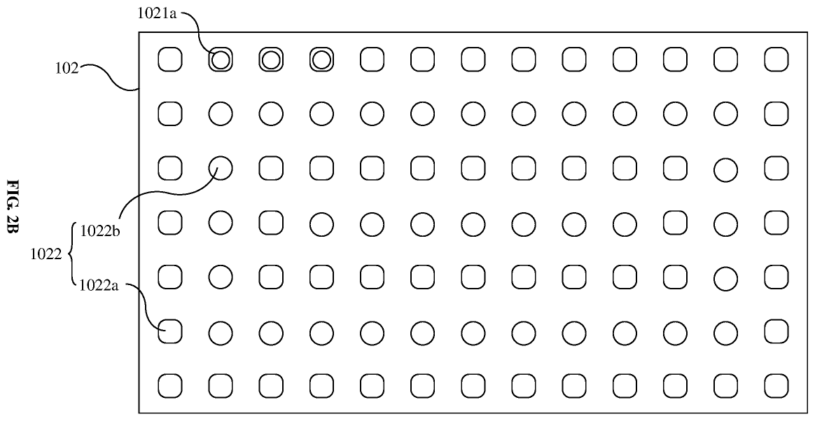

Still referring to FIGS. 2A-2B, in a top view, the first outlet 1022a may have a shape selected from one, or a combination of a circle, a bar, and a polygon. Similarly, the second outlet 1022b may have a shape selected from one, or a combination of a circle, a bar, and a polygon. The shapes of the first outlet 1022a and the second outlet 1022b may be the same, that is, the first outlet 1022a and the second outlet 1022b are both circular or polygonal in shape. Alternatively, the shape of the first outlet 1022a and the shape of the second outlet 1022b may be different, that is, the shape of the first outlet 1022a is one or a combination of a circle or a polygon, and the shape of the second outlet 1022b is another one or another combination of a circle or a polygon.

In addition, depending on different distances between the first outlet 1022a and a central position O of the gas spraying device 102, the shapes of the first outlet 1022a at different positions may also be different. Similarly, depending on different distances between the second outlet 1022b and a central position O of the gas spraying device 102, the shapes of the second outlet 1022b at different positions may also be different.

Further, depending on different distances between the first outlet 1022a and the central position O of the gas spraying device 102, the sizes of the first outlet 1022a at different positions may also be different. Similarly, depending on different distances between the second outlet 1022b and the central position O of the gas spraying device 102, the sizes of the second outlet 1022b at different positions may also be different

Specifically, as shown in FIG. 2A, in a top view, the first outlet 1022a and the second outlet 1022b may be arranged in a circle, and the first outlet 1022a and the second outlet 1022b are alternately arranged. Further, a plurality of the first outlets 1022a are arranged circumferentially to form a first virtual circle 1022c, and a plurality of the second outlets 1022b are arranged circumferentially to form a second virtual circle 1022d, the first virtual circle 1022c and the second virtual circles 1022d are alternately arranged.

Referring to FIG. 2B. In a top view, the first outlet 1022a have a shape of a combination of a circle and a polygon, and the shape of the second outlet 1022b is a circle. The shapes of the first outlet 1022a and the second outlet 1022b can be selected according to the actual situation, the present application will not illustrate all options, and those skilled in the art may select the shapes of the first outlet 1022a and the second outlet 1022b according to the actual situation.

The size of the first outlets 1022a may be equal to different from the channel size of the first reaction gas channel 1021a, and as shown in FIG. 2B, the size of part of the first outlets 1022a is larger than the channel size of the first reaction gas channel 1021a. That is, if the first outlet 1022a is circular, the diameter of the first outlet 1022a is greater than or equal to 0.2 mm and less than or equal to 0.6 mm; and further, the diameter of the first outlet 1022a is equal to 0.3 mm. If the shape of the first outlet 1022a is a polygon, the width of the first outlet 1022a in a top view is greater than or equal to 0.2 mm and less than or equal to 0.6 mm; and further, the width of the first outlet 1022a in a top view is equal to 0.3 mm. Similarly, the size of the second outlet 1022b can be obtained, which will not be repeated herein for brevity.

When the channel sizes of the first reaction gas channel 1021a and the second reaction gas channel 1021b become thinner, and the sizes of the first outlet 1022a and the second outlet 1022b become smaller, one having a relatively low flow rate of the first gas 1041 and the second gas 1042 can be distributed more uniformly when entering the reaction chamber 101, and thereby the uniformity of film formation can be improved.

Still referring to FIGS. 1A and 1B, the vapor deposition apparatus further includes a back plate 107, the back plate 107 is located above the gas spraying device 102, the back plate 107 provided with a gas inlet 1071 communicating with outside of the reaction chamber 101 and communicating with the reaction gas channel 1021 to allow the reaction gas to directly enter the reaction chamber 101, and prevent the back plate 107 from being etched by the cleaning gas 1043, thus reducing the number of overhauls and improving utilization rate of the machine.

Further, when the reaction gas channel 1021 includes the first reaction gas channel 1021a and the second reaction gas channel 1021b that are spaced apart from each other, the back plate 107 includes a first gas inlet 1071a communicating with outside of the reaction chamber 101 and communicating with the first reaction gas channel 1021a, and a second gas inlet 1071b communicating with the outside of the reaction chamber 101 and communicating with the second reaction gas channel 1021b.

In addition, one of the gas inlets communicating with the first reaction gas channel 1021a or the second reaction gas channel 1021b and communicating with the outside of the reaction chamber 101 may be provided at the side of the reaction chamber 101. Specifically, as shown in FIG. 1B, the back plate 107 includes the first gas inlet 1071a communicating with the outside of the reaction chamber 101 and communicating with the first reaction gas channel 1021a, and the side of the reaction chamber 101 includes the second gas inlet 1071b communicating with the outside of the reaction chamber 101 and communicating with the second reaction gas channel 1021b.

The present application only provide the embodiments, in which the reaction gas channel 1021 includes a first reaction gas channel 1021a and a second reaction gas channel 1021b that are spaced apart from each other; the first reaction gas channel 1021a includes a first outlet 1022a communicating with the reaction chamber 101, the second reaction gas channel 1021b includes a second outlet 1022b communicating with the reaction chamber 101. However, it is conceivable that the reaction gas channel 1021 may further include reaction gas channels such as a third reaction gas channel and a fourth reaction gas channel that are spaced apart from the first reaction gas channel 1021a and the second reaction gas channel 1021b. The third reaction gas channel includes a third outlet communicating with the reaction chamber 101, the fourth reaction gas channel includes an fourth outlet such as a fourth outlet communicating with the reaction chamber 101, and the cleaning gas channel 103 is located below the first outlet 1022a, the second outlet 1022b, the third outlet, the fourth outlet, etc., so as to improve the utilization rate of the machine and ensure that when the reaction gas enters the reaction chamber 101, residue is prevented from appearing in a non-film forming area of the reaction chamber 101, which impacts accuracy of the film formation. The number of the reaction gas channels 1021 can be adjusted according to actual needs, which will not be repeated in the present application for brevity, and can be adjusted by those skilled in the art according to actual needs.

The vapor deposition apparatus provided in the embodiments of the present application includes: a reaction chamber 101, a gas spraying device 102, and a cleaning gas channel 103, wherein the gas spraying device 102 includes a reaction gas channel 1021, the reaction gas channel 1021 includes an outlet 1022 communicating with the reaction chamber; the cleaning gas channel 103 and the reaction gas channel 102 are spaced apart from each other, such that the probability of generating the residual produce in the reaction chamber 101 can be reduced, and the uniformity of film formation and the utilization rate of the machine are improved.

In the above embodiments, the descriptions of each embodiment have their own emphasis. The parts that are not described in detail in an embodiment can be referred to the detailed descriptions in other embodiments above, which will not be repeated herein for brevity.

The vapor deposition apparatus provided in the embodiments of the present application has been described in detail above. Specific examples are used in this document to explain the principles and implementation of the present invention. The descriptions of the above embodiments are only for understanding the method of the present invention and its core ideas, to help understand the technical solution of the present application and its core ideas, and a person of ordinary skill in the art should understand that it can still modify the technical solution described in the foregoing embodiments, or equivalently replace some of the technical features. Such modifications or replacements do not depart the spirit of the corresponding technical solutions beyond the scope of the technical solutions of the embodiments of the present application.

What is claimed is:

1. A vapor deposition apparatus, comprising: a reaction chamber, a gas spraying device, and a cleaning gas channel, wherein
the gas spraying device comprises a reaction gas channel, and the reaction gas channel comprises an outlet communicating with the reaction chamber; and
the cleaning gas channel is spaced apart from the reaction gas channel.

2. The vapor deposition apparatus according to claim 1, wherein the cleaning gas channel is located below the outlet of the reaction gas channel.

3. The vapor deposition apparatus according to claim 2, wherein the reaction gas channel comprises a first reaction gas channel and a second reaction gas channel spaced apart from each other, the first reaction gas channel comprises a first outlet communicating with the reaction chamber, the second reaction gas channel comprises a second outlet communicating with the reaction chamber, and the cleaning gas channel is located below the first outlet and the second outlet.

4. The vapor deposition apparatus according to claim 1, further comprising a back plate located above the gas spraying device, wherein the back plate is provided with a gas inlet communicating with outside of the reaction chamber and communicating with the reaction gas channel.

5. The vapor deposition apparatus according to claim 3, wherein the first reaction gas channel communicates with outside of the reaction chamber, and a first gas enters the reaction chamber through the first outlet of the first reaction gas channel, the second reaction gas channel communicates with the outside of the reaction chamber, and a second gas enters the reaction chamber through the second outlet of the second reaction gas channel.

6. The vapor deposition apparatus according to claim 3, further comprising a back plate located above the gas spraying device, wherein the back plate is provided with a first gas inlet communicating with outside of the reaction chamber and communicating with the reaction gas channel, and a second gas inlet communicating with the outside of the reaction chamber and communicating with the second reaction gas channel.

7. The vapor deposition apparatus according to claim 3, wherein a size of the first reaction gas channel is greater than or equal to 0.2 mm and less than or equal to 0.6 mm.

8. The vapor deposition apparatus according to claim 3, wherein a size of the second reaction gas channel is greater than or equal to 0.2 mm and less than or equal to 0.6 mm.

9. The vapor deposition apparatus according to claim 3, wherein, in a top view, the first outlet is one or a combination of a circle, a bar, and a polygon.

10. The vapor deposition apparatus according to claim 3, wherein, in a top view, the second outlet is one or a combination of a circle, a bar, and a polygon.

11. The vapor deposition apparatus according to claim 5, wherein the first gas comprises one of an oxidizing gas and a reducing gas.

12. The vapor deposition apparatus according to claim 11, wherein the second gas comprises the other one of the oxidizing gas and the reducing gas.

13. The vapor deposition apparatus according to claim 12, wherein the oxidizing gas comprises oxygen and/or nitrous oxide; and the reducing gas comprises silane and/or phosphine.

14. The vapor deposition apparatus according to claim 1, wherein a cleaning gas enters the reaction chamber through the cleaning gas channel, and the cleaning gas comprises nitrogen trifluoride and/or argon gas.

15. The vapor deposition apparatus according to claim 1, wherein a size of the reaction gas channel is greater than or equal to 0.2 mm and less than or equal to 0.6 mm.

16. The vapor deposition apparatus according to claim 15, wherein the size of the reaction gas channel is equal to 0.3 mm.

17. The vapor deposition apparatus according to claim 1, further comprising a stage directly facing the outlet.
